(19) United States
(12) Patent Application Publication
(10) Pub. No.: US 2016/0001942 A1
(43) Pub. Date: Jan. 7, 2016

(54) LID, GAS CELL, SEALING METHOD FOR GAS CELL, MANUFACTURING METHOD FOR LID, AND LID ARRAY SUBSTRATE

(71) Applicant: SEIKO EPSON CORPORATION, Tokyo (JP)

(72) Inventors: Eiichi FUJII, Shiojiri-shi (JP); Kimio NAGASAKA, Hokuto-shi (JP)

(21) Appl. No.: 14/750,123

(22) Filed: Jun. 25, 2015

(30) Foreign Application Priority Data
Jul. 2, 2014 (JP) 2014-136538

(51) Int. Cl. B65D 53/06; G01R 33/26; B65D 43/02

(52) U.S. Cl. CPC B65D 53/06; B65D 43/02; G01R 33/26

(57) ABSTRACT

A sealing method for gas cell includes a bonding step of bonding a projection part to a substrate as a lid for sealing a gas cell, a positioning step of positioning the substrate with respect to a gas cell main body by inserting the projection part bonded to the substrate into an opening part provided in the gas cell main body, and a sealing step of sealing the gas cell main body by bonding the substrate and the gas cell main body by a sealing material in a positioned state.

### BACKGROUND

1. Technical Field

The present invention relates to a lid, a lid array substrate, a manufacturing method for lid, a gas cell having the lid, and a sealing method for gas cell using the lid.

2. Related Art

In related art, optical pumping magnetic sensors are known as sensors used for biomagnetic measurement apparatuses that detect magnetic fields generated from hearts of living bodies or the like. For the magnetic sensor, a gas cell in which an alkali metal gas is sealed is used. To seal the alkali metal gas in the gas cell, for example, it is necessary to load the alkali metal gas from a predetermined opening part provided in the gas cell, and then, seal the opening part. There are various methods for sealing. Patent Document 1 (JP-A-2000-203891) discloses a method of inserting a glass tube into a cylindrical hole formed using glass, applying a liquid frit seal to the end of the cylindrical hole in a ring form, and then, melting and sealing the seal. Patent Document 2 (JP-A-2007-329140) discloses a method of bringing a solid ring-shaped frit seal into contact with an end of a thin tube formed using glass through which a current supply member is inserted, heating and melting the seal to be infiltrated into a gap between the thin tube and the current supply member. Further, Patent Document 3 (JP-A-2013-172811) discloses a method of reducing occurrence of cracking due to contraction of a sealing material at a step of sealing a gas cell using the sealing material.

However, the methods respectively have pluralities of steps, and more simple methods are required. For example, as a sealing method for gas cell, there is a method of sealing a hole provided in a gas cell with a lid. At the step of sealing the gas cell, displacement of the lid with respect to the gas cell main body may occur. In the technologies disclosed in Patent Documents 1 to 3 may reduce occurrence of cracking, but may not reduce occurrence of displacement of the lid.

### SUMMARY

An advantage of some aspects of the invention is to solve at least apart of the problems described above, and the invention can be implemented as the following application examples.

### Application Example 1

A lid according to this application example of the invention includes a lid substrate, and a projection part, wherein the projection part is provided on a first surface of the lid substrate, and, in a plan view of the first surface from a side of the projection part, a first sealing material is provided in an area outside of the projection part in the first surface.

According to this configuration, when a predetermined opening part of a structure having the opening part is closed, positioning is performed by inserting the projection part into the predetermined opening part, the projection part is bonded to the structure using the first sealing material, and thereby, the lid may be placed in a proper position with respect to the structure and the predetermined opening part may be reliably closed.

### Application Example 2

In the lid according to the application example of the invention, it is preferable that the projection part is bonded to the first surface by a second sealing material.

According to this configuration, the projection part is bonded to the first surface by the second sealing material, and thus, the lid substrate and the projection part may be separately prepared and bonded. Thereby, the shape of the projection part may be made appropriate for the opening part of the used structure and they may be formed using different materials.

### Application Example 3

In the lid according to the application example of the invention, it is preferable that, in the plan view of the first surface from the side of the projection part, the first sealing material is continuously provided in a form surrounding the projection part.

According to this configuration, the first sealing material is continuously provided around the projection part in the plan view, and thereby, the opening part may be closed more reliably.

### Application Example 4

In the lid according to the application example of the invention, it is preferable that the first sealing material is a frit.

According to this configuration, the manufacture of the lid substrate may be made easier using the frit. Further, the material of the frit may be easily made suitable for the material of the projection part or the like.

### Application Example 5

In the lid according to the application example of the invention, it is preferable that the area where the first sealing material is provided on the first surface is a pearskin finish surface.

According to this configuration, with the pearskin finish surface, bonding using the frit may be made stronger.

### Application Example 6

In the lid according to the application example of the invention, it is preferable that the second sealing material is a frit.

According to this configuration, the manufacture of the lid substrate may be made easier using the frit. Further, the material of the frit may be easily made suitable for the material of the structure having the predetermined opening part or the like.

### Application Example 7

In the lid according to the application example of the invention, it is preferable that an area where the second sealing material is provided on the first surface is a pearskin finish surface.

According to this configuration, with the pearskin finish surface, bonding using the frit may be made stronger.

### Application Example 8

In the lid according to the application example of the invention, it is preferable that, in the plan view of the first surface from the side of the projection part, a section area of the projection part by a plane in parallel to a contact surface between the first surface and the projection part is the maximum in another part than an end of the projection part at an opposite side of the first surface.

According to this configuration, the section area of the projection part is the maximum in the other part than the end, and thereby, the end of the projection part may be easily inserted into the predetermined opening part of the structure. Further, the position where the section area of the projection part in the other part than the end portion is optional, and the shape of the projection part may be made suitable for the shape of the structure.

### Application Example 9

In the lid according to the application example of the invention, it is preferable that the projection part is a sphere.

According to this structure, because of the spherical shape, it is not necessary to consider the orientation of the projection part when the projection part is bonded to the first surface and handling is easier.

### Application Example 10

A gas cell according to this application example of the invention is a gas cell including a sealed opening part, wherein the opening part is sealed by the lid, and the projection part enters the opening part and the lid substrate is fixed to the gas cell by the first sealing material.

According to this structure, the opening part of the gas cell may be closed in the appropriate form.

### Application Example 11

A sealing method for opening part in a gas cell according to this application example of the invention includes, preferably, positioning to fix the lid described above by inserting the projection part in the lid into the opening part.

According to this method, the opening part of the gas cell may be appropriately sealed using the lid.

### Application Example 12

A manufacturing method for lid according to this application example of the invention is a manufacturing method for a lid that seals a predetermined opening part including a first sealing material placing step of providing a first sealing material according to the predetermined opening part in each of a plurality of areas of one substrate, a projection part bonding step of bonding a projection part using a second sealing material to each of the plurality of areas, and a dicing step of dividing the respective plurality of areas of the substrate into respective pieces, wherein, in a plan view of each of the plurality of areas, the area where the first sealing material is provided is an area outside of an area overlapping with the projection part when the projection part is bonded.

According to this method, a plurality of lids having the projection parts may be easily manufactured.

### Application Example 13

In the manufacturing method for lid according to the application example of the invention, it is preferable that each of the first sealing material and the second sealing material is a frit.

According to this method, the first sealing material and the second sealing material may be easily formed.

### Application Example 14

In the manufacturing method for lid according to the application example of the invention, it is preferable to further include machining the area where the first sealing material is provided on a surface of the first substrate into a pearskin finish surface, and machining the area where the second sealing material is provided on the surface of the first substrate into a pearskin finish surface.

According to this method, sealing for the predetermined structure using the first sealing material and the second sealing material may be made more reliable.

### Application Example 15

In the manufacturing method for lid according to the application example of the invention, it is preferable that the projection part is a sphere.

According to this method, the projection part is the sphere and it is not necessary to consider the orientation of the projection part in the manufacturing process, and the manufacture is easier.

### Application Example 16

In the manufacturing method for lid according to the application example of the invention, it is preferable that the dicing step is performed after the projection part bonding step.

According to this method, placement of the plurality of projection parts may be made easier.

### Application Example 17

A lid array substrate according to this application example of the invention is preferably as the one substrate after the projection part bonding step in the manufacturing method for lid.

According to this configuration, after the projection part bonding step, the lid array substrate having the function of the projection parts may be obtained.

### BRIEF DESCRIPTION OF THE DRAWINGS

The invention will be described with reference to the accompanying drawings, wherein like numbers reference like elements.

FIG. 1 is a block diagram showing a configuration of a magnetometric apparatus.

FIG. 2 is an appearance diagram of a gas cell array.

FIG. 3 is a sectional view of the gas cell.

FIG. 4 is a flowchart showing a manufacturing process of the gas cell.

FIG. 5 is a top view of a positioning jig for glass balls.

FIG. 6 is a side view of a lid array substrate to which the glass balls are fixed.

FIG. 7 is a perspective view of the lid array substrate to which the glass balls are fixed.

FIG. 8 is a top view of the lid array substrate to which the glass balls are fixed.

FIG. 9 is an appearance diagram of a diced lid substrate.

FIG. 10 shows a state of fine adjustment of the position of the lid by the glass ball.

### DESCRIPTION OF EXEMPLARY EMBODIMENTS

As below, embodiments according to the invention will be explained using the drawings. Note that the drawings used for the explanation are for convenience sake and, for example, size ratios of respective component elements of configurations shown in the drawings are not limited to those shown in the drawings.

### First Embodiment

The embodiment is an example using a lid according to the invention for sealing of a magnetometric apparatus.

### 1. Configuration of Magnetometric Apparatus

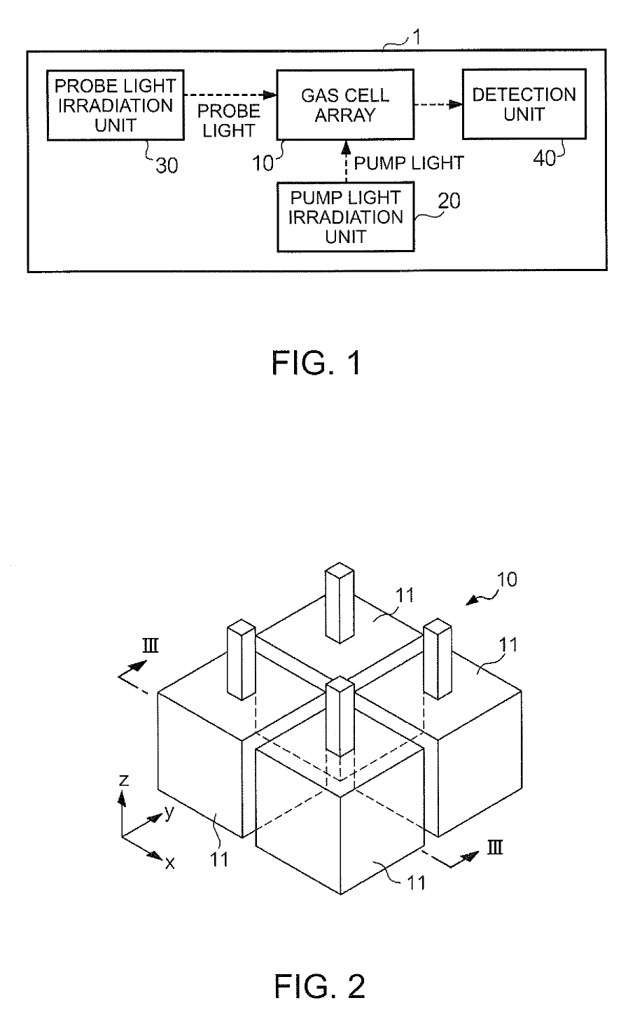

FIG. 1 is a schematic block diagram showing a configuration of a magnetometric apparatus 1. The magnetometric apparatus 1 is a biological state measuring apparatus that measures a magnetic field generated from a living body such as a magnetic field generated from a heart (cardiac magnetic field) or a magnetic field generated from a brain (cerebral magnetic field) as an index of the state of the living body. The magnetometric apparatus 1 has a gas cell array 10, a pump light irradiation unit 20, a probe light irradiation unit 30, and a detection unit 40.

The gas cell array 10 includes a plurality of gas cells. Within the respective plurality of gas cells, an alkali metal gas (e.g. cesium (Cs)) is sealed.

The pump light irradiation unit 20 outputs pump light that interacts with alkali metal atoms (e.g. light having a wavelength of 894 nm corresponding to the D1 line of cesium). The pump light has a circularly-polarized light component. When irradiated with the pump light, the outermost electrons of the alkali metal atoms are excited and spin polarization is caused. The spin-polarized alkali metal atoms precess due to a magnetic field B generated by a measured object. The spin polarization of one alkali metal atom is relaxed with time, however, the pump light is continuous wave (CW) light and formation and relaxation of spin polarization are repeated simultaneously in parallel and continuously. As a result, stationary spin polarization is formed as a whole atom cluster.

The probe light irradiation unit 30 outputs probe light having a linearly-polarized light component. Before and after transmission through the gas cell, the plane of polarization of the probe light rotates due to the Faraday effect. The rotation angle of the polarization plane is expressed as a function of the magnetic field B.

The detection unit 40 detects the rotation angle of the probe light. The detection unit 40 has a photodetector that outputs a signal in response to an amount of incident light, a processor that processes the signal, and a memory that stores data. The processor calculates the magnitude of the magnetic field B using the signal output from the photodetector. Further, the processor writes data representing the calculation result in the memory. In this manner, a user may obtain information of the magnetic field B generated from the measured object.

FIG. 2 is an appearance diagram of the gas cell array 10. In this example, the gas cell array 10 has a plurality (2×2) of gas cells 11 two-dimensionally arranged on an xy-plane.

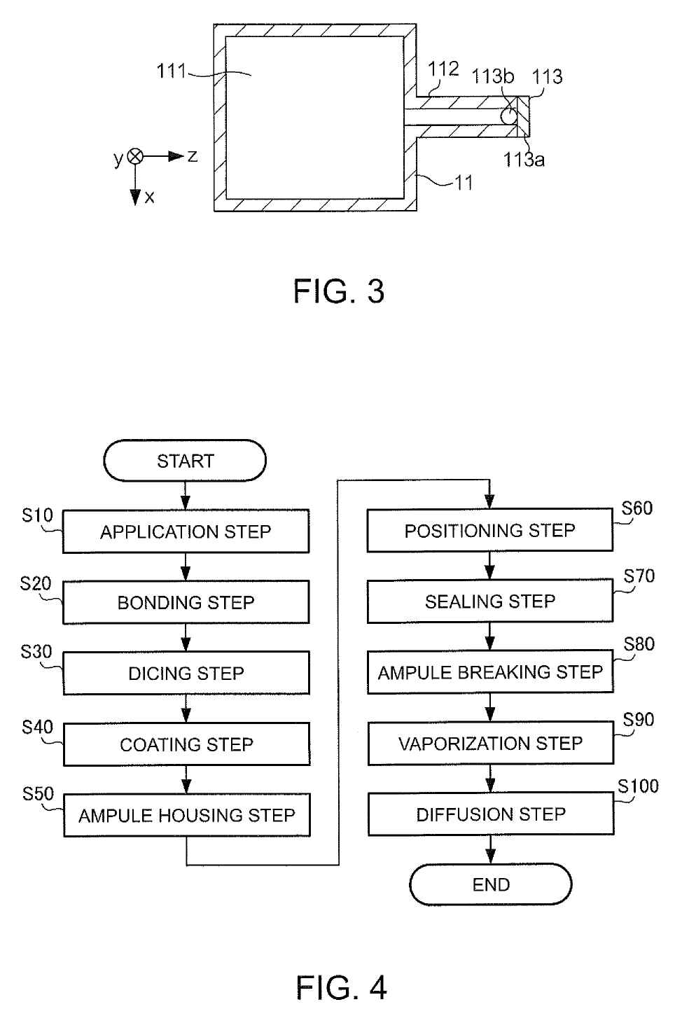

FIG. 3 is a sectional view along III-III of the gas cell 11 forming the gas cell array 10. This section is in parallel to the xz-plane. The gas cell 11 is a cell (box) having a rectangular parallelepiped shape in which the alkali metal gas is sealed. The gas cell 11 is formed using a material having light transmissivity such as quartz glass or borosilicate glass. For example, the gas cell 11 is manufactured by glass molding. Note that the gas cell 11 may be formed by glass machining.

The gas cell 11 has a principal chamber 111 in which the alkali metal gas is sealed. The principal chamber 111 is open to the outside by an exhaust pipe 112. The exhaust pipe 112 has a tubular shape. One end of the exhaust pipe 112 is connected to a vacuum pump (not shown) for evacuation or, as appropriate, introduction of the alkali metal gas. The opening part of the exhaust pipe 112 is sealed by a lid 113.

The lid 113 includes a substrate 113a (an example of a lid substrate) and a glass ball 113b bonded by a sealing material. The substrate 113a is manufactured using the same material as that of the main body of the gas cell 11 (e.g. quartz glass). The glass ball 113b is an example of a projection part. In this example, the glass ball 113b has a spherical shape. Accordingly, a section in parallel to the bonding surface between the lid 113 and the exhaust pipe 112 at the end of the glass ball 113b is smaller than a section in parallel to the bonding surface at the center of the glass ball 113b. Further, the size of the largest part of the section in parallel to the bonding surface of the glass ball 113b is smaller than the size of the opening part of the gas cell 11. The lid 113 and the exhaust pipe 112 are bonded so that the glass ball 113b of the lid 113 may enter the opening part of the exhaust pipe 112.

In the lid 113, a sealing material is applied to a position surrounding the opening part of the exhaust pipe 112 of the gas cell 11, and the lid 113 and the gas cell 11 main body are bonded by the sealing material. It is preferable that the bonding surface between the lid 113 and the exhaust pipe 112 is a rough surface i.e. the so-called pearskin finish surface for increasing bonding strength to the sealing material. In this example, a low-melting-point glass frit having a lower melting point than the glass as the material of the gas cell 11 main body is used for the sealing material.

### 2. Manufacturing Method for Gas Cell

FIG. 4 is a flowchart showing a manufacturing process of the gas cell 11. In this example, prior to sealing of the gas cell 11, the lid 113 is manufactured at steps S10 to S30.

First, at step S10 (application step), the sealing material for bonding the substrate 113a and the gas cell 11 main body is applied to the substrate 113a in a ring form using a dispenser. Concurrently, a sealing material is also applied to the part around the center of the ring as a sealing material for fixing the glass ball 113b to the substrate 113a. The substrate 113a is one of a plurality of pieces formed by division of one substrate. In this example, the sealing material is applied to one lid array substrate 114 before division in an array form. The sealing material is applied to one lid array substrate 114 in an array form, and thereby, formation of the plurality of substrates 113a is easier.

At step S20 (bonding step), the glass balls 113b are bonded to the lid array substrate 114. In this example, a positioning jig 2 for positioning of the glass balls is used and a plurality of the glass balls 113b are bonded to one lid array substrate 114.

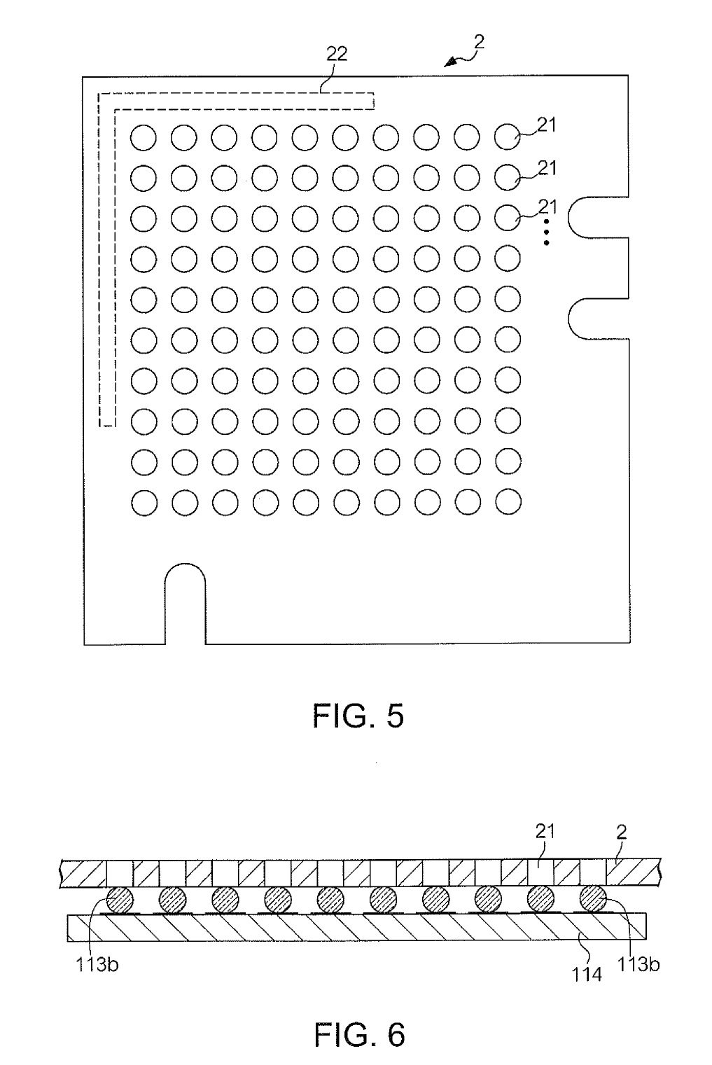

FIG. 5 is a top view of the positioning jig 2 for the glass balls 113b. A plurality of holes 2 for positioning of the glass balls 113b are provided in the positioning jig 2. The positioning jig 2 is set on the lid array substrate 114 to which the sealing material has been applied, and the glass balls 113b are arranged. In the example, calcination is performed for fusing the sealing material and the glass balls 113b are fixed to the lid array substrate 114. The positioning jig 2 has a guide (projection) 22 for positioning the lid array substrate 114.

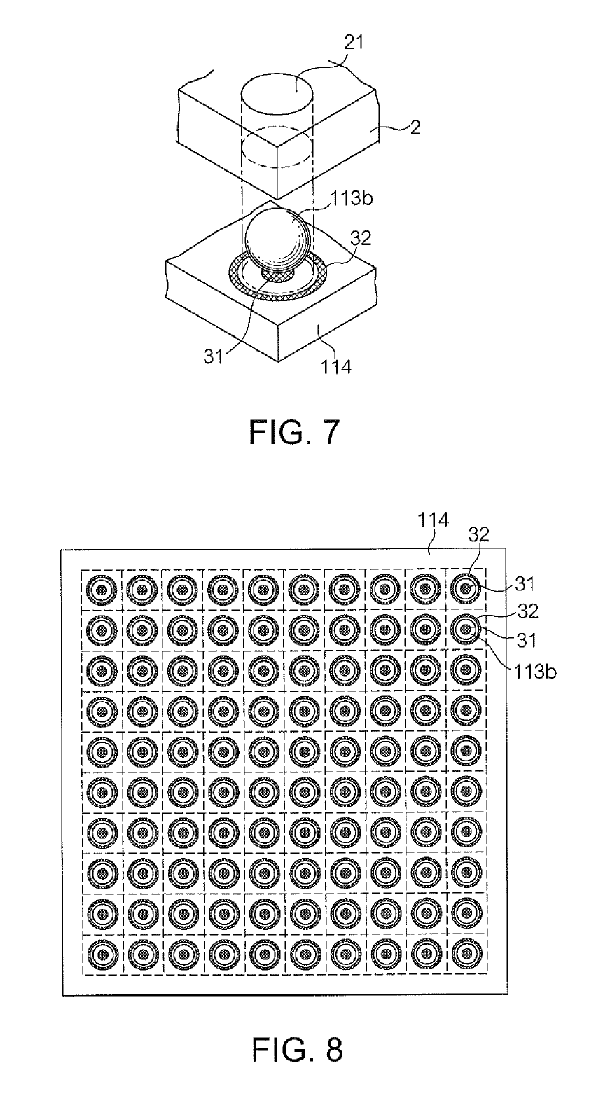

FIG. 6 is a side view of the lid array substrate 114 to which the glass balls 113b are fixed by the positioning jig 2. Further, FIG. 7 is a perspective view of a part of the lid array substrate 114 shown in FIG. 6. In FIGS. 6 and 7, to facilitate understanding of the invention, the states in which the positioning jig 2 is lifted from the lid array substrate 114 are shown, however, actually, the positioning jig 2 is used by overlapping with the lid array substrate 114. As shown in the drawings, in the substrate 113a, sealing materials 31 are applied to the positions where the glass balls 113b are arranged and sealing materials 32 are applied in the circumference forms (ring forms) around the sealing materials 31 at step S10. The glass balls 113b are fixed to the lid array substrate 114 by the sealing materials 31.

If the glass ball 113b is too small, rattles may be caused, positioning accuracy may be lower, and displacement of the lid 113 may occur at sealing. For example, supposing that the hole diameter of the opening part of the gas cell 11 is φ1.2 mm, the diameter of the glass ball 113b is preferably from φ1.05 to 1.15 mm. Note that, in the example, the thickness of the substrate 113a is about 2.7 mm.

FIG. 8 is a top view of the lid array substrate 114 to which the glass balls 113b are arranged. At step S20, the plurality of glass balls 113b are fixed to the lid array substrate 114.

Referring to FIG. 4 again, at step S30 (dicing step), the lid array substrate 114 is diced.

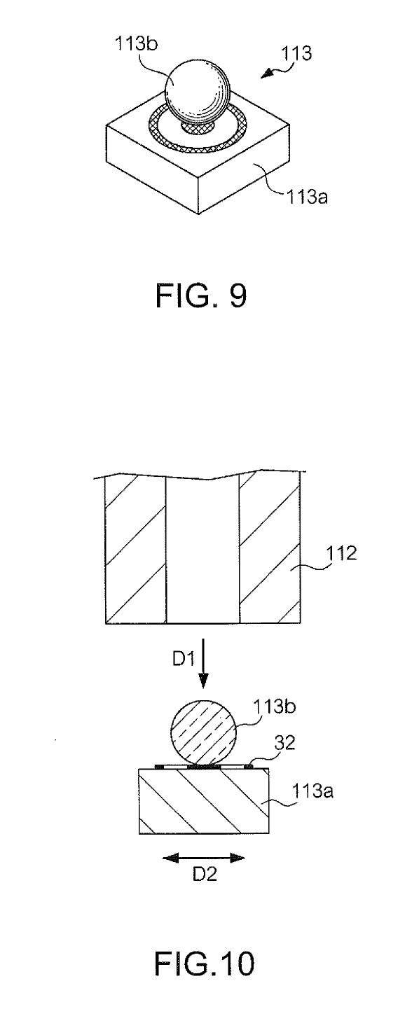

FIG. 9 is an appearance diagram of the diced lid substrate. The lid array substrate 114 is diced, and thereby, the plurality of lids 113 are completed.

Referring to FIG. 4 again, at step S40 (coating step), a coating layer is formed on inner walls of the gas cell 11. For the coating layer, e.g., paraffin is used. The coating layer is applied by a dry process or wet process. At step S50 (ampule housing step), an ampule is housed in the gas cell 11. An alkali metal solid is encapsulated in the ampule.

At step S60 (positioning step), positioning of the lid 113 manufactured at steps S10 to S30 with respect to the main body of the gas cell 11 is performed. In the example, the glass ball 113b bonded to the substrate 113a is put into the opening part of the gas cell 11, and the positioning of the lid 113 with respect to the gas cell 11 main body is performed. In the example, the lid 113 is placed on a stage of a sealing apparatus (not shown) and the opening part of the exhaust pipe 112 of the gas cell 11 is brought closer thereto. In this regard, the glass ball 113b of the lid 113 serves as a guide for positioning.

FIG. 10 shows a state of fine adjustment of the position of the lid 113 by the glass ball 113b. The exhaust pipe 112 moves in a direction of an arrow D1 and the glass ball 113b enters the opening part of the exhaust pipe 112 and, for example, the position of the lid 113 is finely adjusted in directions of an arrow D2 and determined. Thereby, even when the center of the exhaust pipe 112 is misaligned with the center of the lid 113, appropriate fine adjustment is performed and the lid 113 is set in a preferable position with respect to the exhaust pipe 112.

Referring to FIG. 4 again, at step S70 (sealing step), the gas cell 11 is sealed. The sealing of the gas cell 11 is performed in a vacuum state. In the example, in an environment of heating under vacuum, the lid 113 is positioned and the sealing material 32 is fused, and further, the sealing material is weighted and crushed. Thereby, the substrate 113a and the main body of the gas cell 11 are bonded by the sealing material 32 and the gas cell 11 is sealed by the lid 113.

At step S80 (ampule breaking step), the ampule is broken. Specifically, the ampule is irradiated with a laser beam focused on the ampule and the ampule is pierced. At step S90 (vaporization step), the alkali metal solid within the ampule is vaporized. Specifically, the gas cell 11 is heated for heating the alkali metal solid, and the solid is vaporized. At step S100 (diffusion step), the alkali metal gas is diffused. Specifically, the alkali metal gas is held at a certain temperature (desirably at the higher temperature than the room temperature) in a fixed period and diffused.

In related art, when the opening part of the gas cell is sealed, the bonding area between the gas cell and the lid by the sealing material may be smaller due to displacement of the lid covering the opening part. There may be a difference in expansion due to heat between the sealing material and the lid substrate, and the frit quantity is made as small as possible for prevention of frit cracking. Specifically, the width of the ring of the frit applied in the ring form is narrower and the diameter of the ring is not much larger than the diameter of the opening part. Accordingly, the sealing must be performed while finely adjusting the position where the lid is placed on the stage of the sealing apparatus with high accuracy. If the position where the lid is placed is only slightly misaligned, the bonding area of the gas cell and the lid is smaller. Further, it is conceivable to provide an alignment mechanism for positioning of the lid, however, a large-scaled mechanism is required for operation in an environment of heating under vacuum and cost rise is unavoidable. Therefore, when high-accuracy adjustment is impossible, the frit application area is increased in consideration of the misalignment, and the risk of frit cracking is higher for the increase as described above.

On the other hand, in the embodiment, the projection part (glass ball 113b) is provided on the lid 113 and the projection part serves as the guide for positioning at the sealing step. Thereby, the accuracy of positioning of the lid 113 at the sealing step may be increased without using the high-accuracy alignment mechanism.

Further, the positioning accuracy increases and the bonding area by the sealing material is not smaller. Furthermore, the area for application of the seating material may be made smaller on the substrate 113a, and the amount of applied sealing material may be made smaller. As a result, cracking of the sealing material caused by the difference in expansion due to heat may be prevented and reliability of sealing of the gas cell 11 may be made higher. The amount of the sealing material may be reduced, and thereby, generation of an outer gas may be suppressed and reliability of the gas cell 11 may be improved.

In addition, in the embodiment, the plurality of glass balls 113b may be arranged on one lid array substrate 114 in the array form at once using the positioning jig 2 or the like, and thereby, a plurality of lids having projection parts may be easily formed. Further, the glass balls 113b bonded at the bonding step of step S20 have the spherical shapes and are not direction-dependent, and their arrangement is easier.

### Second Embodiment

The invention is not limited to the above described embodiment and various modifications may be made. As below, several modified examples including the embodiment will be explained. Two or more of the following modified examples may be combined for use. Further, in the following embodiments including the embodiment, the same numbers may be assigned to component elements having the same configurations as those of the first embodiment and their explanation may be omitted.

In the above described embodiment, the glass ball 113b of the lid 113 has the spherical shape, however, the shape of the projection part provided on the lid is not limited to that. The shape of the projection part may be a hemisphere, cone, triangular pyramid, or the like. Further, in the above described embodiment, the glass ball 113b having the section in parallel to the bonding surface between the lid 113 and the exhaust pipe 112 at the end of the glass ball 113b smaller than the section in parallel to the bonding surface at the center of the glass ball 113b is used as the projection part, however, the shape of the projection part is not limited to that. The shape of the projection part may be e.g. a cylindrical shape or rectangular parallelepiped shape.

### Third Embodiment

The material of the projection part is not limited to glass. For example, the projection part may be a member formed using ceramic. Note that it is preferable that the material of the projection part is closer to the substrate 113a in coefficient of thermal expansion.

### Fourth Embodiment

In the first embodiment, the gas cell 11 having the principal chamber ill and the exhaust pipe 112 is used, however, the shape of the gas cell 11 is not limited to the above described shape. For example, a gas cell without the exhaust pipe 112 may be used. In this case, an opening part may be provided in the principal chamber in which the alkali metal gas is sealed and the opening part may be sealed by the lid having the projection part.

### Fifth Embodiment

In the first embodiment, the sealing material 32 is placed in the ring form on the substrate 113a, however, the placement shape of the sealing material 32 is not limited to that. The sealing material may be placed in a rectangular outer frame shape, for example. Further, in the above described embodiment, the sealing material 32 is applied to the lid 113, however, the sealing material 32 may be applied to the gas cell main body side.

### Sixth Embodiment

In the first embodiment, the plurality of lids 113 are manufactured by bonding the plurality of glass balls 113b to the lid array substrate 114 at once and dicing the lid array substrate 114 with the plurality of glass balls 113b bonded thereto. The manufacturing method for the lid 113 is not limited to that. The lid 113 may be manufactured by bonding one glass ball 113b to one substrate 113a.

### Seventh Embodiment

The manufacturing method for gas cell is not limited to that exemplified in FIG. 4. Another step may be added to the steps shown in FIG. 4. Or, the sequence of the steps may be changed or part of the steps may be omitted. For example, the coating step may be omitted.

### Eighth Embodiment

The shape of the gas cell is not limited to that explained in the embodiment. In the embodiment, the example in which the shape of the gas cell is a rectangular parallelepiped is explained, however, the shape of the gas cell may be another polyhedron than the rectangular parallelepiped or partially curved like a cylinder or the like. For example, the gas cell may have a reservoir (metal reservoir) for holding the alkali metal solid when the temperature is lower than the temperature at which alkali metal atoms are solidified. Note that it is only necessary that the alkali metal is gasified at least at measurement, but not necessary that the alkali metal is constantly in the gas state.

### Ninth Embodiment

The specific details of the ampule breaking step is not limited to that explained in the embodiment. The ampule may have a part in which two materials having different coefficients of thermal expansion are bonded. In this case, at the ampule breaking step, the ampule (the whole gas cell housing the ampule) is heated instead of laser beam irradiation. At heating, heat at the degree at which the ampule is broken due to the difference in coefficient of thermal expansion is applied. Further, the ampule may be crashed against the inner wall of the principal chamber 111 and broken by applying mechanical impact and vibration to the ampule.

In another example, the sealing step may be performed under a condition that an inert gas such as a rare gas (buffer gas) is sealed in addition to the alkali metal gas within the gas cell. That is, the sealing of the gas cell 11 may be performed in an inert gas atmosphere.

### Tenth Embodiment

In the above described embodiment and modified examples, the example in which the alkali metal atoms are introduced into the gas cell in the solid state for introduction is explained. However, the state when the alkali metal atoms are introduced into the gas cell is not limited to the solid. The alkali metal atoms may be introduced into the gas cell in any state of solid, liquid, or gas. Further, a capsule may be used in place of the ampule.

Further, at the coating step, a coating material may be contained in an ampule or the like, the ampule may be put inside of the gas cell in advance before sealing, and, after sealing, the ampule maybe broken by laser irradiation or the like and the coating is performed using gas-phase deposition.

### Eleventh Embodiment

The application of the gas cell 11 is not limited to the magnetic sensor. For example, the gas cell 11 may be used for an atomic oscillator.

The invention may be widely applied in a range without departing from the scope of the invention.

The entire disclosure of Japanese Patent Application No. 2014-136538, filed Jul. 2, 2014 is expressly incorporated by reference herein.

What is claimed is:

1. A lid comprising:
a lid substrate; and
a projection part,
wherein the projection part is provided on a first surface of the lid substrate, and
in a plan view of the first surface from a side of the projection part, a first sealing material is provided in an area outside of the projection part in the first surface.

2. The lid according to claim 1, wherein the projection part is bonded to the first surface by a second sealing material.

3. The lid according to claim 1, wherein, in the plan view of the first surface from the side of the projection part, the first sealing material is continuously provided in a form surrounding the projection part.

4. The lid according to claim 1, wherein the first sealing material is a frit.

5. The lid according to claim 4, wherein the area where the first sealing material is provided on the first surface is a pearskin finish surface.

6. The lid according to claim 2, wherein the second sealing material is a frit.

7. The lid according to claim 6, wherein an area where the second sealing material is provided on the first surface is a pearskin finish surface.

8. The lid according to claim 1, wherein, in the plan view of the first surface from the side of the projection part, a section area of the projection part by a plane in parallel to a contact surface between the first surface and the projection part is the maximum in another part than an end of the projection part at an opposite side of the first surface.

9. The lid according to claim 1, wherein the projection part is a sphere.

10. A gas cell sealed by a lid, comprising a sealed opening part,
wherein the opening part is sealed by the lid according to claim 1, and
the projection part enters the opening part and the lid is fixed to the gas cell by the first sealing material.

11. A gas cell sealed by a lid, comprising a sealed opening part,
wherein the opening part is sealed by the lid according to claim 2, and
the projection part enters the opening part and the lid is fixed to the gas cell by the first sealing material.

12. A gas cell sealed by a lid, comprising a sealed opening part,
wherein the opening part is sealed by the lid according to claim 3, and
the projection part enters the opening part and the lid is fixed to the gas cell by the first sealing material.

13. A sealing method for opening part in a gas cell having an opening part, comprising positioning to fix the lid according to claim 1 by inserting the projection part in the lid into the opening part.

14. A sealing method for opening part in a gas cell having an opening part, comprising positioning to fix the lid according to claim 2 by inserting the projection part in the lid into the opening part.

15. A manufacturing method for a lid that seals a predetermined opening part, comprising:
providing a first sealing material according to the predetermined opening part in each of a plurality of areas of one substrate;
bonding a projection part using a second sealing material to each of the plurality of areas; and
dividing dicing the respective plurality of areas of the substrate into respective pieces,
wherein, in a plan view of each of the plurality of areas, the area where the first sealing material is provided is an area outside of an area overlapping with the projection part when the projection part is bonded.

16. The manufacturing method according to claim 12, wherein each of the first sealing material and the second sealing material is a frit.

17. The manufacturing method according to claim 12, further comprising:
machining the area where the first sealing material is provided on a surface of the first substrate into a pearskin finish surface; and
machining the area where the second sealing material is provided on the surface of the first substrate into a pearskin finish surface.

18. The manufacturing method according to claim 12, wherein the projection part is a sphere.

19. The manufacturing method according to claim 12, wherein the dicing is performed after the projection part bonding.

20. A lid array substrate as the one substrate after the projection part bonding in the manufacturing method for lid according to claim 16.
